(19) United States
(12) Patent Application Publication
(10) Pub. No.: US 2025/0318093 A1
(43) Pub. Date: Oct. 9, 2025

(54) DC-Link Capacitor Assembly and Cooling Device Used Therefor

(71) Applicant: Robert Bosch GmbH, Stuttgart (DE)

(72) Inventors: Jian Zhu, Suzhou (CN); Sally Chen, Suzhou (CN)

(21) Appl. No.: 19/098,372

(22) Filed: Apr. 2, 2025

(30) Foreign Application Priority Data
Apr. 3, 2024 (CN) 2024 2067 9118.0

(51) Int. Cl. H05K 7/20; H02M 3/00

(52) U.S. Cl. CPC H05K 7/20927; H02M 3/003

(57) ABSTRACT

A DC-link capacitor assembly for a power conversion unit is disclosed. The DC-link capacitor assembly includes an input capacitor, an output capacitor, a bus duct, and a box body. The input capacitor and the output capacitor are housed in the bus duct and are in electrical connection with a terminal on the bus duct. The input capacitor, the output capacitor and the bus duct are housed together and fixed within the box body and formed as an independent component together with the box, the independent component being capable of being mounted directly to the power conversion unit and electrically connected to an external component through a terminal on the bus duct. By way of the above, the DC-link capacitor is allowed to withstand large currents and helps reduce the total size of PTU. Also disclosed is a cooling device for the above-mentioned DC-link capacitor assembly, which effectively solves the problem of high heat generation of DC-link capacitors.

This application claims priority under 35 U.S.C. § 119 to application no. CN 2024 2067 9118.0, filed on Apr. 3, 2024 in China, the disclosure of which is incorporated herein by reference in its entirety.

The present utility model relates to a power electronic device and a cooling system used therefor, particularly to a DC-link capacitor assembly and a cooling device for the DC-link capacitor assembly.

### BACKGROUND

A power conversion unit (PTU) is a power electronic device in a hydrogen vehicle, which can change low voltage direct current to high voltage direct current, or vice versa. After conversion, the current will be supplied to other devices through an interface of the PTU. One of the key components in the PTU is a DC-link capacitor capable of filtering power ripples produced in a DC-DC converter (direct current-direct current converter).

The DC-link capacitor includes two parts, an input capacitor and an output capacitor. The input capacitor and the output capacitor are typically soldered separately on a printed circuit board (PCB) with little capacitance. Thus, in order to satisfy the same current, more capacitors are typically needed, which will result in a larger size of the PCB, which will further result in a larger size of the PTU. This will not meet customers' needs.

In addition, due to the large amount of heat generated by DC-link capacitors, effective cooling of DC-link capacitors is required to ensure their stable long-term operation.

Accordingly, there is a need in the art for a DC-link capacitor capable of withstanding larger current and reducing footprint, and there is also a need in the art for a cooling device capable of efficiently cooling the DC-link capacitor.

### SUMMARY

A technical problem to be solved by the present utility model is to provide a DC-link capacitor assembly that can provide a large current to meet PTU needs when the dimensions requirements are met.

In order to solve the above technical problems, the present utility model provides a DC-link capacitor assembly for a power conversion unit. The DC-link capacitor assembly includes an input capacitor, an output capacitor, a bus duct, and a box body. The input capacitor and the output capacitor are housed in the bus duct and are in electrical connection with a terminal on the bus duct. The input capacitor, the output capacitor and the bus duct are housed together and fixed within the box body and formed as an independent component together with the box body, and the independent component can be directly mounted to the power conversion unit and electrically connected with an external component through a terminal on the bus duct.

According to a preferred example of the present utility model, the bus duct housing the input capacitor and the output capacitor is bonded or snapped onto the box body.

According to a preferred example of the present utility model, the bus duct housing the input capacitor and the output capacitor is bonded to the box body by a thermal adhesive.

In accordance with a preferred example of the present utility model, the box body is made of a metallic or non-metallic thermal material, or is made of plastic.

In accordance with a preferred example of the present utility model, a connecting structure for mounting the independent component onto the power conversion unit is provided on the box body, the connecting structure being a male lug having a hole for receiving a screw to thread the independent component to the power conversion unit.

Another technical problem to be solved by the present utility model is to provide an efficient heat dissipation device for DC-link capacitors used in high-pressure products to ensure normal operation of the DC-link capacitors.

In order to solve the above technical problems, the present utility model also provides a cooling device for the above-mentioned DC-link capacitor assembly. The cooling device includes at least one of an upper cooler mounted abutting a bus duct of the DC-link capacitor assembly from above and a lower cooler mounted abutting a box body of the DC-link capacitor assembly from below.

According to a preferred example of the present utility model, the upper cooler and the lower cooler are flat fluid coolers.

According to a preferred example of the present utility model, the upper cooler is provided with an opening that exposes a terminal of the bus duct, and the size and position of the opening are suitable for exposing all terminals of the bus duct.

According to a preferred example of the present utility model, the lower cooler is a housing cooler of the power conversion unit.

In accordance with a preferred example of the present utility model, when the cooling device comprises both an upper cooler and a housing cooler, the upper cooler is mounted to the housing cooler and is in fluid communication with the housing cooler, such that a coolant is able to simultaneously pass through the upper cooler and the housing cooler and take away heat.

Using the technical solution of the present utility model, the input and output capacitors are integrated into a box so that the DC-link capacitor assembly can withstand large currents, which helps reduce the overall size of the PTU. In addition, the adoption of a cooling device, especially the construction of dual coolers, can further solve the problem of high heat generation of DC-link capacitors.

### BRIEF DESCRIPTION OF THE DRAWINGS

In order to make the present utility model more fully understood by those skilled in the art, specific embodiments of the present utility model will be described in detail below in conjunction with the attached drawings. Here,

FIG. 1 is a top view of a DC-link capacitor assembly of the present utility model;

FIG. 2 is a stereoscopic exploded view of the DC-link capacitor assembly shown in FIG. 1;

FIG. 3 is a stereoscopic exploded view of a cooling device for a DC-link capacitor assembly of the present utility model; and

FIG. 4 is an assembled stereoscopic view of the cooling device shown in FIG. 3.

### REFERENCE SIGNS LIST

1 DC-link Capacitor Assembly
11 Input Capacitor
12 Output Capacitor
13 Bus Duct
131 Terminal
14 Box Body
141 Connecting Structure
2 Cooling Device
21 Upper Cooler
211 Opening
22 Lower Cooler.

### DETAILED DESCRIPTION

In order to make the present utility model clearer, one specific example of the present utility model is described in detail below in conjunction with the attached drawings. However, the present utility model is not limited to the examples described below.

It is to be noted that the orientation term “upper,” “lower,” “top,” and “bottom” as used herein is convenient to illustrate the structure of the product only with reference to the attached drawings, and the orientation is indicated as upper and lower and at the top or bottom in the attached drawings only, and does not represent the actual direction of use of the product.

In accordance with one aspect of the present disclosure, a DC-link capacitor assembly 1 is provided. This DC-link capacitor assembly 1 is used in a power conversion unit (PTU) in a new energy vehicle to filter power ripples produced in a DC-DC converter to provide a stable voltage for the associated subsequent components.

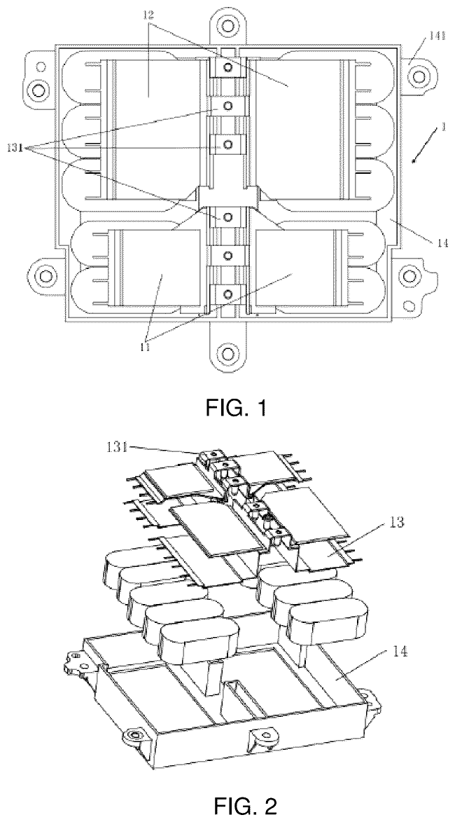

FIGS. 1 to 2 show the DC-link capacitor assembly 1, wherein FIG. 1 is a top view of the DC-link capacitor assembly 1, and FIG. 2 is a stereoscopic exploded view of the DC-link capacitor assembly 1.

As shown in FIGS. 1 to 2, the DC-link capacitor assembly 1 of the present utility model includes an input capacitor 11, an output capacitor 12, a bus duct 13, and a box body 14. Both the input capacitor 11 and the output capacitor 12 are housed in and electrically connected to the bus duct 13. The electrical connection is achieved by electrically connecting the positive and negative electrodes of the capacitor to the positive and negative terminals of the bus duct 13 respectively. The connection between the capacitor and the bus duct 13 may be achieved by wires, soldering points, or dedicated connectors. The input capacitor 11, the output capacitor 12, and the bus duct 13 of the present utility model are housed together and fixed in the box body 14 and constructed as an independent component together with the box body 14. The independent component is connected to an external component through a terminal 131 of the bus duct 13. The independent component can be installed directly onto the PTU housing as a whole. Using the DC-link capacitor assembly of the present utility model can reduce the footprint of capacitor and simplify the layout of the PTU.

Preferably, the bus duct 13 housing the input capacitor 11 and the output capacitor 12 is fixed into the box body 14, such as by being pasted into the box body 14 by an adhesive, thereby formed integrally with the box body 14. Optionally, the adhesive is a thermal adhesive. Any other suitable connection method may be used. For example, the bus duct 13 housing the input capacitor 11 and the output capacitor 12 may be snapped into the box body 14 by structural fit. In this instance, an adaptation structure for snapping the bus duct 13 may be provided at the bottom or side of the box body, or the inner dimension of the box body 4 may be made slightly smaller than the outer dimension of the bus duct 13, and the two may be secured together by interference fit. There are no restrictions on the material of the box body 14. For example, the box body 14 may be made of plastic. However, it is preferred that the box body 14 is made of a rigid material with good heat dissipation, such as metallic or non-metallic thermal materials. For example, the box body 14 may be made of copper, aluminum, silver, graphite, graphene, silicon carbide, diamond, ceramic, and the like. According to a preferred example, the box body 14 may be made of aluminum. In the case of larger current or more heat generated, an opening on the box body may be considered to assist with heat dissipation. A thermal adhesive can also assist in heat dissipation. Each of the above embodiments may be used alone or in combination.

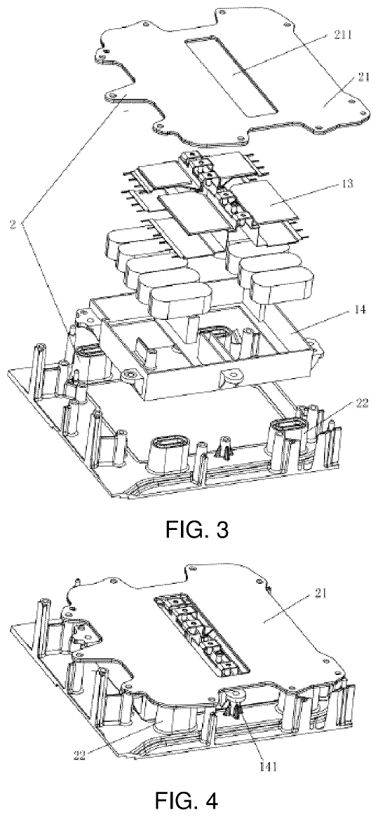

Preferably, a connecting structure 21 is provided on the box body 14 to mount the DC-link capacitor assembly 1 onto a PTU housing or to install other components such as a cooling device on the DC-link capacitor assembly 1. In the illustrated example, the connecting structure 141 is shown as a male lug with a hole that allows a screw, pin, or bolt, etc. to pass through to attach the DC-link capacitor assembly 1 to an associated component, e.g., to the PTU housing as shown in FIGS. 3 to 4.

Preferably, a cooling device may be installed on the DC-link capacitor assembly 1. For example, a cooler may be disposed above and/or below the DC-link capacitor assembly 1. The cooler is disposed abutting the bus duct from above or abutting the box body 14 from below such that the cooler is in close contact with the DC-link capacitor assembly 1 for ease of heat transmission and improved heat dissipation. Preferably, the cooler can be secured to the connecting structure 141 of the box body 14. As shown in FIG. 3, an upper cooler 21 may be disposed above the DC-link capacitor assembly 1.

In accordance with this aspect of the present utility model, the input capacitor, the output capacitor, and the bus duct are placed in a box body to form an independent component, thereby reducing the footprint of the capacitors. In addition, the independent component can be mounted directly into the PTU housing, which can simplify the layout of the PTU, thereby making the structure of the PTU more compact and reduced in overall size. The DC-link capacitor assembly of the present utility model is able to successfully achieve capacitor functions using a smaller PTU. In addition, because the DC-link capacitor is integrated into an independent component, large-capacity input and output capacitors can be employed, thereby enabling the DC-link capacitor assembly to withstand larger current.

Typically, DC-link capacitors generates a large amount of heat during operation, and effective heat dissipation of DC-link capacitors is needed to ensure their long-term stable operation. Therefore, another aspect of the present utility model also provides a cooling device for a DC-link capacitor assembly, which can help the capacitor to dissipate heat efficiently to ensure its normal operation.

The cooling device 2 for heat dissipation may be disposed around the capacitor, such as above, below, or around the capacitor. The cooling device 2 for heat dissipation may be formed in integral with the input capacitor 11 and the output capacitor 12. For example, it may be a thermal fin disposed on the capacitor. The cooling device may also be an independent device located at an upper part, a lower part, or side of the DC-link capacitor assembly 1. The independent cooling device may be an air-cooled device or a liquid-cooled device. The independent cooling device may be a heat pipe system through which air or coolant may flow through the heat pipe to take away heat. Of course, the above-described cooling device for heat dissipation may be arranged in combination.

The cooling device 2 for the DC-link capacitor assembly 1 according to an example of the present utility model is described below in detail with reference to FIGS. 3 to 4. FIG. 3 shows a stereoscopic exploded view of the cooling device 2 and FIG. 4 shows an assembled view of the cooling device 2 of FIG. 3.

The cooling device 2 for the DC-link capacitor assembly 1 of the present utility model includes at least one of the upper cooler 21 and a lower cooler 22. In other words, the cooling device 2 may include only the upper cooler 21, or only the lower cooler 22, or both the upper cooler 21 and the lower cooler 22.

According to an example, the cooling device 2 may have only the upper cooler 21. The upper cooler 21 can be mounted to the DC-link capacitor assembly 1 by methods of snap-fitting, threaded engagement, adhesion, etc. For example, the upper cooler 21 may be mounted to a male lug 141 on the box body 2 by a protruding structure. As shown in FIG. 3, the upper cooler 21 is located above the DC-link capacitor assembly 1 and abuts the bus duct 13 of the DC-link capacitor assembly 1 from above, both of which are in close contact to improve cooling effects.

Preferably, the upper cooler 21 is provided with an opening 211 at a suitable location so that a terminal 131 of the bus duct 13 is exposed therefrom, thereby enabling the DC-link capacitor assembly 1 to connect to an external component through the terminal 131 thereof. In the illustrated example, the opening 211 is provided along the longitudinal direction in the middle of the upper cooler 21 to expose all terminals 131 of the bus duct 13. The length and width of the opening 211 are adapted to accommodate and expose all of the terminals 131 of the bus duct 13.

The upper cooler 21 may be any form of cooler. According to a preferred example, the upper cooler 21 is an independent flat cooling device that can take away heat from the DC-link capacitor assembly 1 through the circulation of the coolant. Preferably, the area of the plane of the upper cooler 21 is adapted to generally cover the upper surface of the DC-link capacitor assembly 1. Preferably, the upper cooler 21 may have a protruding structure around the periphery to facilitate attachment to the PTU housing or other components.

According to another example, the cooling device 2 for the DC-link capacitor assembly 1 may include only the lower cooler 22. The lower cooler 22 is arranged from below the DC-link capacitor assembly 1 abutting the cassette body 14 to take away the heat of the capacitor from below. The structure of the lower cooler 22 may be generally the same as the structure of the upper cooler 21, but the opening may be omitted. The lower cooler 22 may be an independent cooling device. The lower cooler 22 can be mounted to the box body 14 by methods of snap-fitting, threaded engagement, adhesion, etc. In the example shown in FIGS. 3 to 4, the lower cooler 22 is fixed to the box body 14 of the DC-link capacitor assembly 1 by screws. Preferably, the lower cooler 22 may be a housing cooler of the PTU.

Preferably, the cooling device 2 for the DC-link capacitor assembly 1 includes both the upper cooler 21 and the lower cooler 22. The upper cooler 21 and the lower cooler 22 may be coupled to each other to clamp the DC-link capacitor assembly 1 therebetween. According to a preferred example, the lower cooler 22 may be a housing cooler of the PTU. Where the housing cooler is a liquid-cooled device, the upper cooler 21 may also be configured as a liquid-cooled device, thereby allowing fluid communication between the upper cooler 21 and the housing cooler, enabling the coolant to flow in both coolers, thereby cooling the DC-link capacitor assembly 1 from above and below simultaneously. In this way, the bottom side of the DC-link capacitor assembly can contact the surface of the housing cooler, and then the upper cooler is assembled onto the PTU housing so that the upper cooler is in communication with the housing cooler, and the cooling water can take away the heat through both coolers. With a dual cooler structure, the problem of high heat generation can be solved more effectively. Therefore, the DC-link capacitor assembly can be used in high voltage products (e.g., PTUs) or other high-power devices with DC-link capacitors.

In summary, the novel structure of the present utility model is improved by integrating the input capacitor and the output capacitor into a box body, which can enable the DC-link capacitor to withstand large currents and help reduce the total size of the PTU. In addition, the cooling device of the present utility model adopts an upper and lower dual cooler structure, which can also effectively solve the problem of high heat generation. Therefore, the DC-link capacitor assembly can be used in high-voltage products or high-power devices.

The above specific examples are only used to illustrate the present utility model, and are not the limitations of the present utility model. Without departing from the inventive concept of the present utility model, one skilled in the art may make various modifications and variations. Therefore, all equivalent technical solutions fall within the protective scope of the present utility model, and the protective scope of the present utility model is defined by the attached claims.

What is claimed is:

1. A DC-link capacitor assembly for a power conversion unit, comprising:
an input capacitor;
an output capacitor;
a bus duct; and
a box body,
wherein the input capacitor and the output capacitor are housed in the bus duct and are in electrical connection with a terminal on the bus duct; and
wherein the input capacitor, the output capacitor, and the bus duct together are housed and fixed within the box body and formed as an independent component together with the box body, the independent component being configured to be mounted directly to the power conversion unit and electrically connected to an external component through a terminal on the bus duct.

2. The DC-link capacitor assembly according to claim 1, wherein the bus duct housing, the input capacitor, and the output capacitor are bonded or snapped onto the box body.

3. The DC-link capacitor assembly according to claim 2, wherein the bus duct housing, the input capacitor, and the output capacitor are bonded to the box body by a thermal adhesive.

4. The DC-link capacitor assembly according to claim 1, wherein the box body is made of a metallic or non-metallic thermal material, or is made of plastic.

5. The DC-link capacitor assembly according to claim 1, wherein the box body is provided with a connecting structure for mounting the independent component onto the power conversion unit, the connecting structure being a male lug with a hole to accommodate a screw to thread the independent component onto the power conversion unit.

6. A cooling device for a DC-link capacitor assembly according to claim 1, wherein the cooling device includes at least one of an upper cooler mounted abutting a bus duct of the DC-link capacitor assembly from above and a lower cooler mounted abutting a box body of the DC-link capacitor assembly from below.

7. The cooling device according to claim 6, wherein the upper cooler and the lower cooler are flat fluid coolers.

8. The cooling device according to claim 6, wherein the upper cooler is provided with an opening that is configured to expose a terminal of the bus duct, the opening being suitably sized and positioned to expose all terminals of the bus duct.

9. The cooling device according to claim 6, wherein the lower cooler is a housing cooler of the power conversion unit.

10. The cooling device according to claim 9, wherein when the cooling device includes both an upper cooler and a housing cooler, the upper cooler is mounted to the housing cooler and is in fluid communication with the housing cooler so that a coolant can pass through both the upper cooler and the housing cooler and take away heat.
